(19) United States
(12) Patent Application Publication
(10) Pub. No.: US 2025/0204071 A1
(43) Pub. Date: Jun. 19, 2025

(54) IMAGE SENSOR INCLUDING NANO-OPTICAL MICROLENS ARRAY AND ELECTRONIC APPARATUS INCLUDING THE SAME

(71) Applicant: SAMSUNG ELECTRONICS CO., LTD., Suwon-si (KR)

(72) Inventors: Hyunsung PARK, Suwon-si (KR); Sookyoung Roh, Suwon-si (KR); Sangeun Mun, Suwon-si (KR); Sungmo Ahn, Suwon-si (KR); Junho Lee, Suwon-si (KR); Choonlae Cho, Suwon-si (KR)

(73) Assignee: SAMSUNG ELECTRONICS CO., LTD., Suwon-si (KR)

(21) Appl. No.: 18/982,358

(22) Filed: Dec. 16, 2024

(30) Foreign Application Priority Data
Dec. 19, 2023 (KR) 10-2023-0186297

(51) Int. Cl. H10F 39/00

(52) U.S. Cl. CPC H10F 39/8063; H10F 39/8023; H10F 39/8053

(57) ABSTRACT

Provided are an image sensor including a nano-optical microlens array and an electronic apparatus including the same. The nano-optical lens array of the image sensor includes a plurality of reference lenses and a plurality of unit lenses. the plurality of reference lenses include a first reference lens disposed at a center of the image sensor, a second reference lens disposed in a first direction from the center of the image sensor, and a third reference lens disposed in a second direction from the center of the image sensor, the second direction forming an angle of 45° or 135° with the first direction. Nanostructures included in the first reference lens, the second reference lens, and the third reference lens have different symmetrical structures.

### CROSS-REFERENCE TO RELATED APPLICATION

This application is based on and claims priority under 35 U.S.C. § 119 to Korean Patent Application No. 10-2023-0186297, filed on Dec. 19, 2023, in the Korean Intellectual Property Office, the disclosure of which is herein incorporated by reference in its entirety.

### BACKGROUND

### 1. Field

One or more example embodiments of the disclosure relate to an image sensor including a nano-optical microlens array and an electronic apparatus including the same.

### 2. Description of the Related Art

As an image sensor becomes gradually smaller, a chief ray angle (CRA) at the edge of the image sensor tends to increase. As the CRA increases at the edge of the image sensor, the sensitivity of pixels positioned at the edge of the image sensor decreases. This may cause the edge of the image to be dark. In addition, complex color calculations are needed to compensate for this phenomenon, which places a burden on a processor that processes an image and slows down an image processing speed.

### SUMMARY

Provided are an image sensor including a nano-optical microlens array and an electronic apparatus including the same.

Additional aspects will be set forth in part in the description which follows and, in part, will be apparent from the description, or may be learned by practice of the presented embodiments of the disclosure.

According to an aspect of an example embodiment, an image sensor includes a sensor substrate including a plurality of sensing elements, a color filter layer disposed on the sensor substrate and including a plurality of color filters, each color filter of the plurality of color filters being configured to transmit a light of a specific wavelength band, and a nano-optical lens array disposed on the color filter layer and including a plurality of nanostructures configured to condense an incident light toward the plurality of sensing elements.

The nano-optical lens array may include a plurality of reference lenses and a plurality of unit lenses.

The plurality of reference lenses may include a first reference lens disposed at a center of the image sensor, a second reference lens disposed in a first direction from the center of the image sensor, and a third reference lens disposed in a second direction from the center of the image sensor, the second direction forming an angle of 45° or 135° with the first direction.

Nanostructures included in the first reference lens, the second reference lens, and the third reference lens may have different symmetrical structures.

The second reference lens and the third reference lens may be disposed on an outermost part of the image sensor.

In an x-y Cartesian coordinate system with the center of the image sensor as an origin, the first reference lens may be disposed at the origin, the second reference lens may be disposed on a y=0 line and/or an x=0 line, and the third reference lens may be disposed on an x=y line and/or an x=−y line.

In an x′-y′ Cartesian coordinate system with a center of the first reference lens as an origin, a normalized size of the first reference lens may be 1×1, and nanostructures included in the first reference lens may be arranged to have a mirror symmetrical structure with respect to x′=y′, x′=+0.25, x′=−0.25, y′=+0.25, and y′=−0.25.

In an x′-y′ Cartesian coordinate system with a center of the second reference lens as an origin, a normalized size of the second reference lens may be 1×1, and nanostructures included in the second reference lens may be arranged to have a mirror symmetrical structure with respect to y′=+0.25 and y′=−0.25.

In an x′-y′ Cartesian coordinate system with a center of the third reference lens as an origin, a normalized size of the third reference lens may be 1×1, and nanostructures included in the third reference lens may be arranged to have a mirror symmetrical structure with respect to x′=y′.

Nanostructures included in each unit lens of the plurality of unit lenses may be configured to have a continuously changing shape and/or arrangement according to positions of the nanostructures on the image sensor, through interpolation based on nanostructures included in each of the first reference lens, the second reference lens, and the third reference lens.

The positions of the nanostructures on the image sensor may be determined through a chief ray angle (CRA) and an azimuthal angle of an incident light.

The nano-optical lens array may have at least one layer, and the at least one layer may include two or more materials having different refractive indices.

The at least one layer may be disposed to have an alignment error with the sensor substrate according to a CRA of an incident light.

A size of each of the plurality of nanostructures may be smaller than a wavelength of a visible light.

Each of the plurality of nanostructures may include at least one of c-Si, p-Si, a-Si, Group III-V compound semiconductor, SiC, TiO₂, SiN₃, ZnS, ZnSe, or Si₃N₄.

The image sensor may further include an anti-reflection layer provided on the nano-optical lens array.

The image sensor may further include a planarization layer disposed between the color filter layer and the nano-optical lens array.

The image sensor may further include an encapsulation layer disposed between the planarization layer and the nano-optical lens array.

The image sensor may further include an etch stop layer disposed between the encapsulation layer and the nano-optical lens array.

According to an aspect of an example embodiment, an electronic apparatus includes a lens assembly configured to form an optical image of an object, an image sensor configured to convert the optical image formed by the lens assembly into an electrical signal, and a processor configured to process the electrical signal generated by the image sensor.

The image sensor includes a sensor substrate including a plurality of sensing elements, a color filter layer disposed on the sensor substrate and including a plurality of color filters, each color filter of the plurality of color filters being configured to transmit a light of a specific wavelength band, and a nano-optical lens array disposed on the color filter layer and including a plurality of nanostructures configured to condense an incident light toward the plurality of sensing elements.

The nano-optical lens array includes a plurality of reference lenses and a plurality of unit lenses.

The plurality of reference lenses include a first reference lens disposed at a center of the image sensor, a second reference lens disposed in a first direction from the center of the image sensor, and a third reference lens disposed in a second direction from the center of the image sensor, the second direction forming an angle of 45° or 135° with the first direction.

Nanostructures included in the first reference lens, the second reference lens, and the third reference lens have different symmetrical structures.

The second reference lens and the third reference lens may be disposed on an outermost part of the image sensor.

In an x-y Cartesian coordinate system with the center of the image sensor as an origin, the first reference lens may be disposed at the origin, the second reference lens may be disposed on a y=0 line and/or an x=0 line, and the third reference lens may be disposed on an x=y line and/or an x=−y line.

The nano-optical lens array may have at least one layer, and the at least one layer may be disposed to have an alignment error with the sensor substrate according to a CRA of an incident light.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a block diagram of an image sensor according to an example embodiment;

FIG. 2 illustrates a pixel arrangement of a pixel array according to an example embodiment;

FIGS. 3A and 3B are cross-sectional views schematically illustrating a configuration of a pixel array of an image sensor according to an example embodiment;

FIG. 4 is a plan view schematically illustrating a configuration of a sensor substrate of a pixel array shown in FIGS. 3A and 3B;

FIG. 5 is a plan view schematically illustrating a configuration of a color filter layer shown in FIGS. 3A and 3B;

FIG. 6 is a plan view illustrating a configuration of a nano-optical lens array shown in FIGS. 3A and 3B;

FIG. 7 is a conceptual view schematically illustrating a camera module according to an example embodiment;

FIG. 8 is a plan view of a nano-optical lens array of an image sensor according to an example embodiment;

FIG. 9A illustrates an arrangement of nanostructures of a first reference lens shown in FIG. 8;

FIG. 9B illustrates an arrangement of nanostructures of a second reference lens shown in FIG. 8;

FIG. 9C illustrates an arrangement of nanostructures of a third reference lens shown in FIG. 8;

FIG. 10A is a cross-sectional view of an image sensor to which a first reference lens shown in FIG. 9A is applied;

FIG. 10B is a cross-sectional view of an image sensor to which a second reference lens shown in FIG. 9B is applied;

FIG. 10C is a cross-sectional view of an image sensor to which a third reference lens shown in FIG. 9C is applied;

FIGS. 11A to 11G illustrate various positions where three reference lenses may be disposed in an image sensor according to example embodiments;

FIG. 12 is a block diagram illustrating an example of an electronic apparatus including an image sensor according to some example embodiments;

FIG. 13 is a block diagram schematically illustrating a camera module of FIG. 12; and

FIGS. 14 and 15 are diagrams illustrating various examples of an electronic apparatus to which an image sensor according to an example embodiment is applied.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, example embodiments will be described in detail with reference to the accompanying drawings. Like reference numerals in the drawings denote like elements, and the size of each element in the drawings may be exaggerated for clarity and convenience of description. Meanwhile, embodiments described below are merely examples, and various modifications may be made from these embodiments.

Hereinafter, what is described as “above” or “on” may include those directly on, underneath, left, and right in contact, as well as above, below, left, and right in non-contact. The singular forms are intended to include the plural forms as well, unless the context clearly indicates otherwise. Also, when a part “includes” any element, it means that the part may further include other elements, rather than excluding other elements, unless otherwise stated.

The term “the” and the similar indicative terms may be used in both the singular and the plural. If there is no explicit description of the order of steps constituting a method or no contrary description thereto, these steps may be performed in an appropriate order, and are not limited to the order described.

In addition, the terms “ . . . unit”, “module”, etc. described herein mean a unit that processes at least one function or operation, may be implemented as hardware or software, or may be implemented as a combination of hardware and software.

Connections of lines or connection members between elements shown in the drawings are illustrative of functional connections and/or physical or circuitry connections, and may be redisposed in an actual device, or may be represented as additional various functional connections, physical connections, or circuitry connections.

The use of all examples or example terms is merely for describing the technical concept in detail, and the scope thereof is not limited by these examples or example terms unless limited by claims.

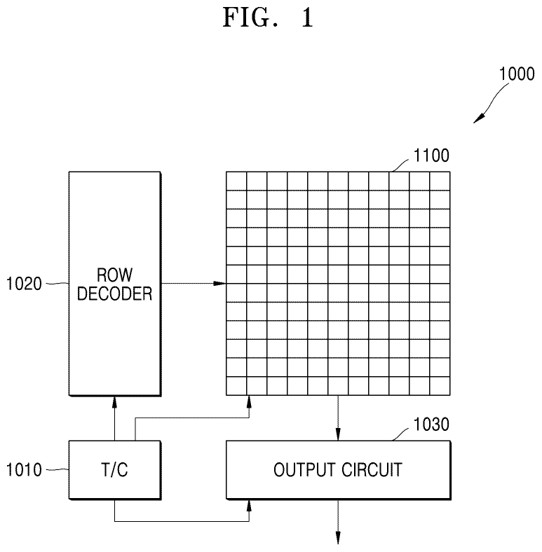

FIG. 1 is a block diagram of an image sensor 1000 according to an example embodiment;

Referring to FIG. 1, the image sensor 1000 may include a pixel array 1100, a timing controller 1010, a row decoder 1020, and an output circuit 1030. The image sensor 1000 may be a charge coupled device (CCD) image sensor or a complementary metal oxide semiconductor (CMOS) image sensor.

The pixel array 1100 may include pixels that are two-dimensionally disposed in a plurality of rows and a plurality of columns. The row decoder 1020 may select one row of the plurality of rows in the pixel array 1100 in response to a row address signal output from the timing controller 1010. The output circuit 1030 may output a photosensitive signal, in a column unit, from a plurality of pixels arranged along the selected row. To this end, the output circuit 1030 may include a column decoder and an analog-to-digital converter (ADC). For example, the output circuit 1030 may include a plurality of ADCs disposed respectively corresponding to the plurality of columns between a column decoder and the pixel array 1100 or one ADC disposed at an output end of the column decoder. The timing controller 1010, the row decoder 1020, and the output circuit 1030 may be implemented as one chip or in separate chips. A processor for processing an image signal output through the output circuit 1030 may be implemented as one chip with the timing controller 1010, the row decoder 1020, and the output circuit 1030.

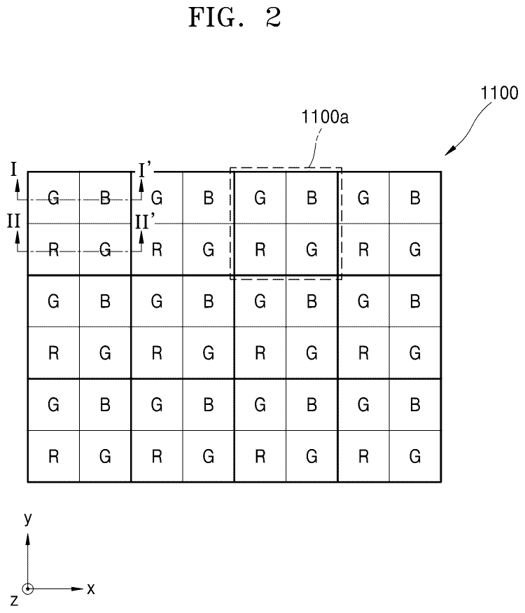

The pixel array 1100 may include a plurality of pixels that sense lights of different wavelengths. An arrangement of the plurality of pixels may be implemented in various ways. FIG. 2 illustrates an example of a pixel arrangement of the pixel array 1100 according to an example embodiment.

FIG. 2 shows a Bayer pattern generally adopted by a general image sensor.

Referring to FIG. 2, one unit pattern 1100a may include four quadrant regions, and first to fourth quadrant regions may respectively indicate a blue pixel (B), a green pixel (G), a red pixel (R), and a green pixel (G). The unit patterns may be repeatedly and two-dimensionally arranged in a first direction (e.g., x-axis direction) and a second direction (e.g., y-axis direction). In other words, two green pixels (G) are arranged in one diagonal direction and one blue pixel (B) and one red pixel (R) are arranged in another diagonal direction in a unit pattern of a 2×2 array. With regard to an overall pixel arrangement of the pixel array 1100, a first row in which a plurality of green pixels (G) and a plurality of blue pixels (B) are alternately arranged in the first direction and a second row in which a plurality of red pixels (R) and the plurality of green pixels (G) are alternately arranged in the first direction may be repeatedly arranged in the second direction.

The pixel array 1100 may be arranged in various ways other than the Bayer pattern. For example, a CYGM arrangement in which a magenta pixel (M), a cyan pixel (C), a yellow pixel (Y), and a green pixel (G) constitute one unit pattern may be used. In addition, an RGBW arrangement in which the green pixel (G), the red pixel (R), the blue pixel (B), and a white pixel (W) constitute one unit pattern may be used. In addition, the unit pattern may have a 3×2 array. The pixels in the pixel array 1100 may be arranged in various ways according to a usage and characteristics of the image sensor 1000. Hereinafter, for illustrative purposes, the pixel array 1100 of the image sensor 1000 is described as having a Bayer pattern, but the operating principles of example embodiments of the disclosure may be applied to other patterns of pixel arrangements than the Bayer pattern. Hereinafter, for convenience, a case where the pixel array 1100 has the Bayer pattern structure is described as an example.

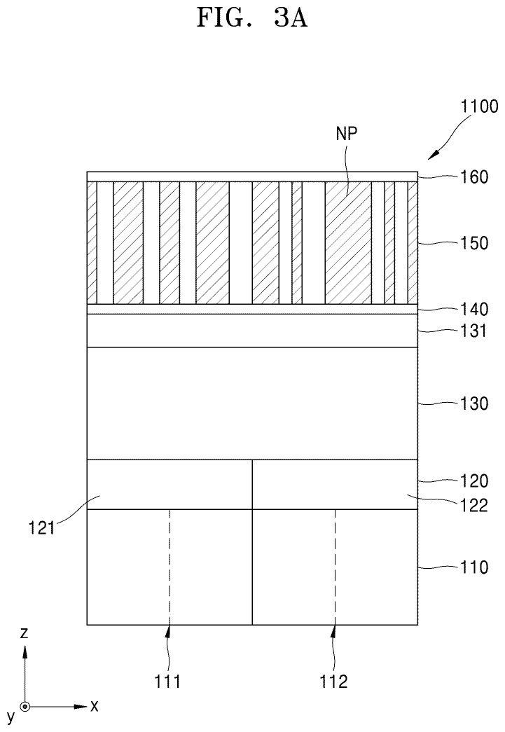

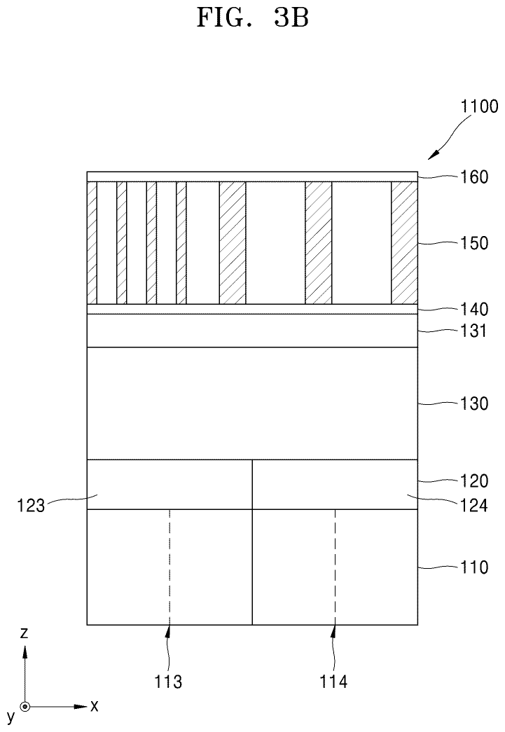

FIGS. 3A and 3B are cross-sectional views schematically illustrating a configuration of the pixel array 1100 of an image sensor according to an example embodiment. FIG. 3A is a cross-sectional view taken along line I-I′ of FIG. 2, and FIG. 3B is a cross-sectional view taken along line II-II′ of FIG. 2. FIG. 3A shows a cross-section including a green pixel and a blue pixel, and FIG. 3B shows a cross-section including a red pixel and a green pixel.

Referring to FIGS. 3A and 3B, the pixel array 1100 may include a sensor substrate 110, a color filter layer 120 disposed on the sensor substrate 110, a transparent planarization layer 130 disposed on the color filter layer 120, a transparent encapsulation layer 131 disposed on the planarization layer 130, and a nano-optical lens array 150 disposed on the encapsulation layer 131. In addition, the pixel array 1100 may further include an etch stop layer 140 disposed between the encapsulation layer 131 and the nano-optical lens array 150. In addition, the pixel array 1100 may further include an anti-reflection layer 160 disposed on a light incident surface of the nano-optical lens array 150. The anti-reflection layer 160 may include at least one layer including a uniform material or nanostructure. In an embodiment, the etch stop layer 140 and the anti-reflection layer 160 may be omitted.

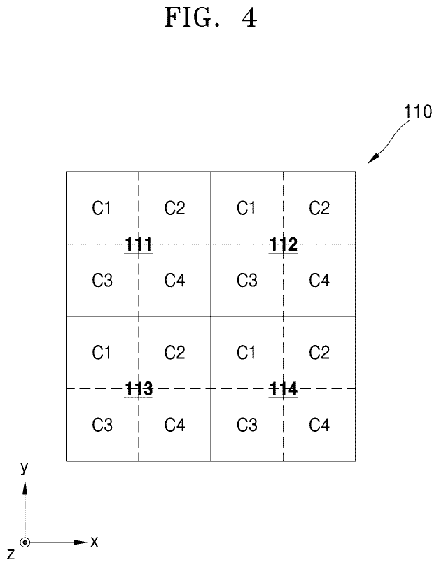

FIG. 4 is a plan view schematically illustrating a configuration of the sensor substrate 110 of the pixel array 1100 shown in FIGS. 3A and 3B. Referring to FIG. 4, the sensor substrate 110 may include a plurality of sensing elements that sense an incident light. For example, the sensor substrate 110 may include a first sensing element 111, a second sensing element 112, a third sensing element 113, and a fourth sensing element 114 that convert the incident light into an electrical signal to generate an image signal. The first sensing element 111, the second sensing element 112, the third sensing element 113, and the fourth sensing element 114 may form one unit Bayer pattern. For example, the first sensing element 111 and the fourth sensing element 114 may correspond to green pixels that sense a green light, the second sensing element 112 may correspond to a blue pixel that senses a blue light, and the third sensing element 113 may correspond to a red pixel that senses a red light.

Only one unit Bayer pattern including the first sensing element 111, the second sensing element 112, the third sensing element 113, and the fourth sensing element 114 is shown in FIGS. 3A, 3B, and 4 as an example, but the pixel array 1100 may include a plurality of Bayer patterns which are two-dimensionally arranged. For example, a plurality of first sensing elements 111 and a plurality of second sensing elements 112 may be alternately arranged in the first direction (x-axis direction) in a cross-section cut at a first position, and a plurality of third sensing elements 113 and a plurality of fourth sensing elements 114 may be alternately arranged in the first direction (x-axis direction) in a cross-section cut at a second position, which is different from the first position in the second direction (y-axis direction) perpendicular to the first direction (x-axis direction).

Each of the first sensing element 111, the second sensing element 112, the third sensing element 113, and the fourth sensing element 114 may include a plurality of photosensitive cells that independently sense the incident light. For example, each of the first sensing element 111, the second sensing element 112, the third sensing element 113, and the fourth sensing element 114 may include first to fourth photosensitive cells C1, C2, C3, and C4. For example, the first to fourth photosensitive cells C1, C2, C3, and C4 may be arranged in a 2×2 array in each of the first sensing element 111, the second sensing element 112, the third sensing element 113, and the fourth sensing element 114. FIG. 4 shows that each of the first sensing element 111, the second sensing element 112, the third sensing element 113, and the fourth sensing element 114 includes the first to fourth photosensitive cells C1, C2, C3, and C4, but four or more independent photosensitive cells may be clustered in a two-dimensional array. For example, each of the first sensing element 111, the second sensing element 112, the third sensing element 113, and the fourth sensing element 114 may include a plurality of independent photosensitive cells arranged in a 3×3 array or a 4×4 array.

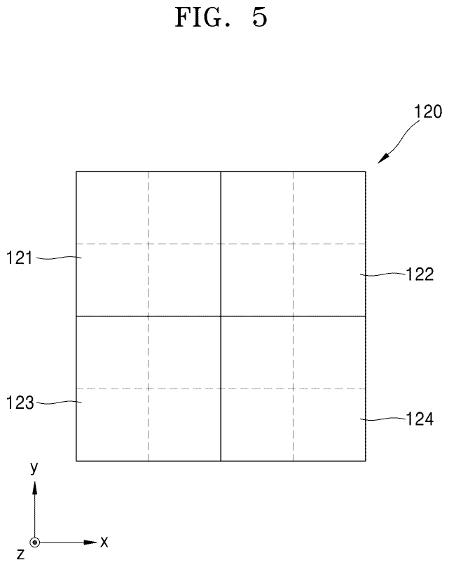

FIG. 5 is a plan view schematically illustrating a configuration of the color filter layer 120 shown in FIGS. 3A and 3B.

Referring to FIG. 5, the color filter layer 120 may include a plurality of color filters that transmit a light of a specific wavelength and absorb lights of other wavelengths. For example, the color filter layer 120 may include a first color filter 121 that transmits a light of a first wavelength and absorbs lights of wavelengths other than the first wavelength, a second color filter 122 that transmits a light of a second wavelength different from the first wavelength and absorbs lights of wavelengths other than the second wavelength, a third color filter 123 that transmits a light of a third wavelength different from the first wavelength and the second wavelength and absorbs lights of wavelengths other than the third wavelength, and a fourth color filter 124 that transmits the light of the first wavelength and absorbs lights of wavelengths other than the first wavelength. FIG. 5 shows only one unit Bayer pattern as an example, but a plurality of first color filters 121 and a plurality of second color filters 122 may be alternately arranged in the first direction (x-axis direction) in a cross-section cut at a first position, and a plurality of third color filters 123 and a plurality of fourth color filters 124 may be alternately arranged in the first direction (x-axis direction) in a cross-section cut at a second position, which is different from the first position in the second direction (y-axis direction) perpendicular to the first direction (x-axis direction).

The first color filter 121 may be disposed to face the first sensing element 111 in a third direction (z-axis direction), the second color filter 122 may be disposed to face the second sensing element 112 in the third direction (z-axis direction), the third color filter 123 may be disposed to face the third sensing element 113 in the third direction (z-axis direction), and the fourth color filter 124 may be disposed to face the fourth sensing element 114 in the third direction (z-axis direction). Accordingly, the first sensing element 111 and the fourth sensing element 114 may sense the light of the first wavelength that has passed through the respectively corresponding first color filter 121 and fourth color filter 124. In addition, the second sensing element 112 may sense the light of the second wavelength that has passed through the corresponding second color filter 122. The third sensing element 113 may sense the light of the third wavelength that has passed through the corresponding third color filter 123. For example, the first color filter 121 and the fourth color filter 124 may be green color filters that transmit a green light, the second color filter 122 may be a blue color filter that transmits a blue light, and the third color filter 123 may be a red color filter that transmits a red light.

Dashed lines inside the first to fourth color filters 121-124 shown in FIG. 5 indicate corresponding boundary lines between photosensitive cells of the first sensing element 111, the second sensing element 112, the third sensing element 113, and the fourth sensing element 114 that respectively face the first to fourth color filters 121-124. As shown in FIGS. 4-5, the first color filter 121, the second color filter 122, the third color filter 123, and the fourth color filter 124 may be disposed to face all photosensitive cells in the respectively corresponding first sensing element 111, second sensing element 112, third sensing element 113, and fourth sensing element 114 in the third direction (z-axis direction). In other words, the first color filter 121 may cover all photosensitive cells in the first sensing element 111, the second color filter 122 may cover all photosensitive cells in the second sensing element 112, the third color filter 123 may cover all photosensitive cells in the third sensing element 113, and the fourth color filter 124 may cover all photosensitive cells in the fourth sensing element 114.

The first color filter 121, the second color filter 122, the third color filter 123, and the fourth color filter 124 of the color filter layer 120 may include, for example, an organic polymer material. For example, the first color filter 121, the second color filter 122, the third color filter 123, and the fourth color filter 124 may each include a colorant, binder resin, polymer photoresist, etc. The first color filter 121 and the fourth color filter 124 may be organic color filters each including a green organic dye or a green organic pigment as a colorant, the second color filter 122 may be an organic color filter including a blue organic dye or a blue organic pigment as a colorant, and the third color filter 123 may be an organic color filter including a red organic dye or a red organic pigment as a colorant. Although not shown in FIGS. 3A, 3B, and 5 for convenience, the color filter layer 120 may further include black matrixes disposed on boundaries between the first color filter 121, the second color filter 122, the third color filter 123, and the fourth color filter 124. The black matrixes may each include, for example, carbon black.

FIGS. 3A and 3B show for convenience that the color filter layer 120 has a flat upper surface, but the upper surface of each of the first color filter 121, the second color filter 122, the third color filter 123, and the fourth color filter 124 may not be flat. In addition, thicknesses of the first color filter 121, the second color filter 122, the third color filter 123, and the fourth color filter 124 and the black matrixes therebetween (which may be further provided) may not be the same. The planarization layer 130 disposed on the color filter layer 120 may provide a flat surface for forming the nano-optical lens array 150 thereon. The planarization layer 130 may include an organic polymer material that is suitable for being stacked on the color filter layer 120 including an organic material and may easily form a flat surface. The organic polymer material forming the planarization layer 130 may have transparent properties to a visible light. For example, the planarization layer 130 may include at least one organic polymer material of epoxy resin, polyimide, polycarbonate, polyacrylate, and polymethyl methacrylate (PMMA). The planarization layer 130 may be formed on the color filter layer 120 by using, for example, spin coating and may have a flat upper surface through heat treatment.

The encapsulation layer 131 may be further disposed on the planarization layer 130. The encapsulation layer 131 may serve as a protective layer that prevents the planarization layer 130 including an organic polymer material from being damaged during a process of forming the nano-optical lens array 150 on the planarization layer 130. In addition, the encapsulation layer 131 may serve as an anti-diffusion layer that prevents a metal component of the color filter layer 120 from passing through the planarization layer 130 and being exposed to the outside due to a high temperature in the process of forming the nano-optical lens array 150. To this end, the encapsulation layer 131 may include an inorganic material. The inorganic material of the encapsulation layer 131 may be formed at a temperature lower than a process temperature for forming the nano-optical lens array 150 and may include a material that is transparent to a visible light. In addition, in order to reduce reflection loss at an interface between the planarization layer 130 and the encapsulation layer 131, a refractive index of the encapsulation layer 131 may be similar to a refractive index of the planarization layer 130. For example, the encapsulation layer 131 may include at least one inorganic material among SiO₂, SiN, and SiON.

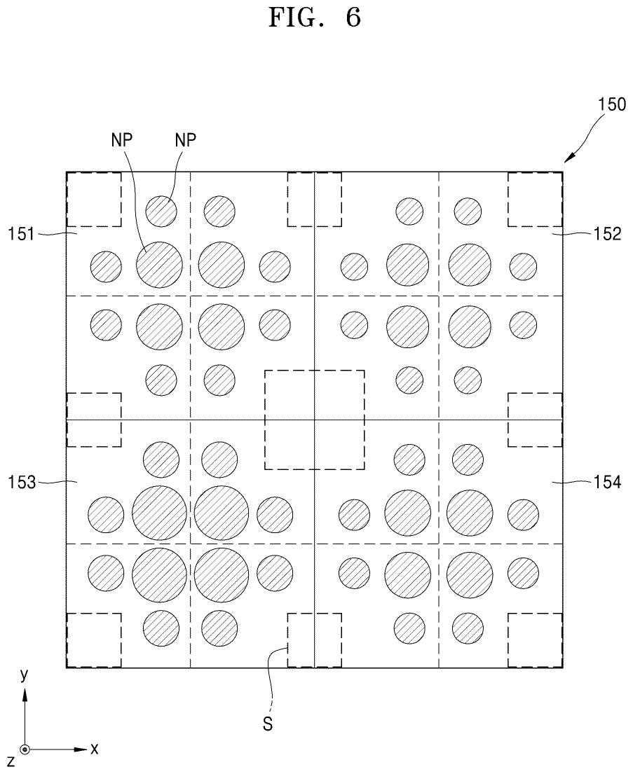

FIG. 6 is a plan view illustrating a configuration of the nano-optical lens array 150 shown in FIGS. 3A and 3B. FIG. 6 shows one unit lens including a first meta-lens 151, a second meta-lens 152, a third meta-lens 153, and a fourth meta-lens 154.

Referring to FIG. 6, the nano-optical lens array 150 may include the first meta-lens 151 corresponding to the first sensing element 111, the second meta-lens 152 corresponding to the second sensing element 112, the third meta-lens 153 corresponding to the third sensing element 113, and the fourth meta-lens 154 corresponding to the fourth sensing element 114. For example, the first meta-lens 151 may be disposed to face the first sensing element 111 in the third direction (z-axis direction), the second meta-lens 152 may be disposed to face the second sensing element 112 in the third direction (z-axis direction), the third meta lens 153 may be disposed to face the third sensing element 113 in the third direction (z-axis direction), and the fourth meta lens 154 may be disposed to face the fourth sensing element 114 in the third direction (z-axis direction). Here, the first meta-lens 151, the second meta-lens 152, the third meta-lens 153, and the fourth meta-lens 154 may constitute one unit lens.

FIG. 6 shows only one unit Bayer pattern as an example, but a plurality of first meta-lenses 151 and a plurality of second meta-lenses 152 may be alternately arranged in the first direction (x-axis direction) in a cross section cut at a first position, and a plurality of third meta-lenses 153 and a plurality of fourth meta-lenses 154 may be alternately arranged in the first direction (x-axis direction) in a cross-section cut at a second position, which is different from the first position in the second direction (y-axis direction) perpendicular to the first direction (x-axis direction).

The nano-optical lens array 150 may include a plurality of nanostructures NP arranged to focus an incident light on the first sensing element 111, the second sensing element 112, the third sensing element 113, and the fourth sensing element 114, respectively. The plurality of nanostructures NP may be arranged to change a phase of a transmitted light that passes through the nano-optical lens array 150 differently according to a position on the nano-optical lens array 150. A phase profile of a transmitted light implemented by the nano-optical lens array 150 may be determined according to a width (or diameter) and a height of each nanostructure NP and/or an arrangement period (or pitch) and/or an arrangement form of the plurality of nanostructures NP. In addition, a behavior of a light passing through the nano-optical lens array 150 may be determined according to the phase profile of the transmitted light. For example, the plurality of nanostructures NP may be arranged to form a phase profile that allows the light passing through the nano-optical lens array 150 to be concentrated. In FIG. 6, “S” indicates a region where the nanostructures NP are not disposed.

The nanostructure NP may have a size smaller than the wavelength of a visible light. The nanostructure NP may, for example, have a size smaller than the blue wavelength. For example, a cross-sectional width (or diameter) of the nanostructure NP may be less than 400 nm, 300 nm, or 200 nm. The height of the nanostructure NP may be about 500 nm to about 1500 nm and may be greater than the cross-sectional width thereof.

The nanostructure NP may include a material that has a relatively high refractive index compared to a surrounding material and a relatively low absorption rate in a visible light band. For example, the nanostructures NP may include two or more materials having different refractive indices. For example, the nanostructures NP may include at least one of c-Si, p-Si, a-Si and Group III-V compound semiconductors (GaP, GaN, GaAs, etc.), SiC, TiO₂, SiN₃, ZnS, ZnSe, Si₃N₄ and/or a combination thereof. The periphery of the nanostructure NP may be filled with a dielectric that has a relatively lower refractive index than the nanostructure NP and has a relatively low absorption rate in a visible light band. For example, the periphery of the nanostructure NP may be filled with siloxane-based spin on glass (SOG), SiO₂, Si₃N₄, Al₂O₃, air, etc.

The refractive index of the nanostructure NP may be about 2.0 or more with respect to a light of a wavelength of about 630 nm, and the refractive index of the surrounding material may be about 1.0 or more and less than 2.0 with respect to a light of a wavelength of about 630 nm. In addition, the difference between the refractive index of the nanostructure NP and the refractive index of the surrounding material may be about 0.5 or more. The nanostructure NP having the difference in the refractive index from the surrounding material may change the phase of a light passing through the nanostructure NP. Accordingly, the phase profile of the transmitted light implemented by the nano-optical lens array 150 may be determined, and the behavior of the light transmitted through the nano-optical lens array 150 may be determined according to the phase profile of the transmitted light. For example, the plurality of nanostructures NP may be arranged to form the phase profile that allows the light passing through the nano-optical lens array 150 to be condensed.

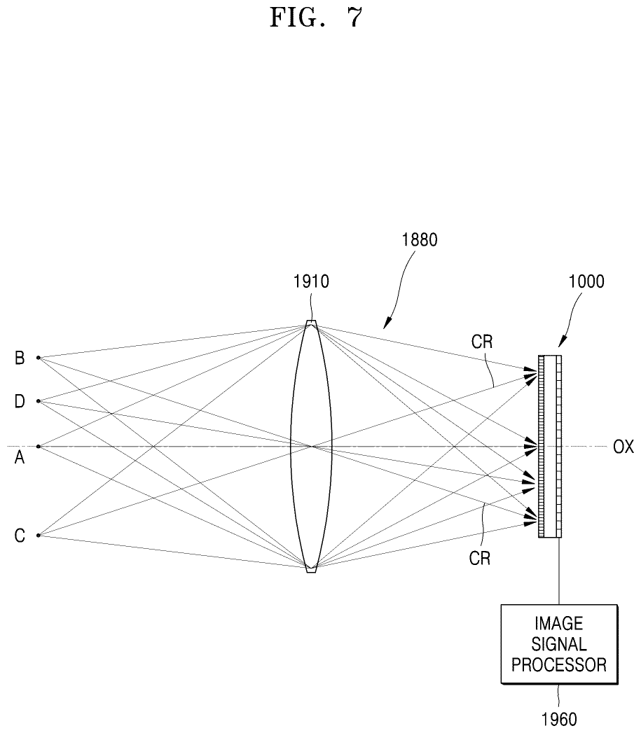

The image sensor 1000 described above may be applied to various optical apparatuses such as a camera module. For example, FIG. 7 is a conceptual diagram schematically illustrating a camera module 1880 according to an example embodiment.

Referring to FIG. 7, the camera module 1880 may include a lens assembly 1910 that forms an optical image by focusing a light reflected from an object, the image sensor 1000 that converts the optical image formed by the lens assembly 1910 into an electrical image signal, and an image signal processor 1960 that processes the electrical image signal output from the image sensor 1000 into an image signal. The camera module 1880 may further include an infrared blocking filter disposed between the image sensor 1000 and the lens assembly 1910, a display panel configured to display an image formed by the image signal processor 1960, and a memory configured to store image data formed by the image signal processor 1960. The camera module 1880 may be mounted, for example, in a mobile electronic apparatus such as a cell phone, a laptop, a tablet personal computer (PC), etc.

The lens assembly 1910 focuses an image of a subject outside the camera module 1880 onto the image sensor 1000, specifically, onto the pixel array 1100 of the image sensor 1000. FIG. 7 briefly shows a single lens for convenience, but the lens assembly 1910 may include a plurality of lenses.

When the pixel array 1100 is accurately located on a focal plane of the lens assembly 1910, a light starting from a point on the subject is re-converged to a point on the pixel array 1100 through the lens assembly 1910. For example, a light starting from a point A on an optical axis OX passes through the lens assembly 1910 and then is converged to the center of the pixel array 1100 on the optical axis OX. A light starting from a point B, C, or D off the optical axis OX and is converged to a point on the periphery of the pixel array 1100 across the optical axis OX by the lens assembly 1910. For example, in FIG. 7, the light starting from the point B above the optical axis OX is converged to a lower edge of the pixel array 1100 across the optical axis OX, and the light starting from the point C is converged to an upper edge of the pixel array 1100 across the optical axis OX. In addition, the light starting from point D located between the optical axis OX and the point B is converged between the center and the lower edge of the pixel array 1100.

Therefore, the lights starting from the points A, B, C, and D are incident on the pixel array 1100 at different angles according to distances between the points A, B, C, and D and the optical axis OX. An incident angle of the light incident on the pixel array 1100 is typically defined as a chief ray angle (CRA). A chief ray (CR) refers to a ray that passes from one point of the subject through the center of the lens assembly 1910 and is incident on the pixel array 1100, and the CRA refers to an angle formed by the chief ray and the optical axis OX. The light starting from the point A on the optical axis OX has a CRA of 0 degree and is incident perpendicularly to the pixel array 1100. As the starting point moves away from the optical axis OX, the CRA increases.

From the perspective of the image sensor 1000, the CRA of the light incident on the center of the pixel array 1100 is 0 degree, and the CRA of the incident light increases toward the edge of the pixel array 1100. For example, the CRA of the light starting from the point B or the point C and incident on the edge of the pixel array 1100 is the largest, and the CRA of the light starting from the point A and incident on the center of the pixel array 1100 is 0 degree. In addition, the CRA of the light starting from the point D and incident between the center and the edge of the pixel array 1100 is less than the CRA of the light starting from the point B and the point C and is greater than 0 degree. The CRA of an incident light incident on pixels varies depending on positions of the pixels within the pixel array 1100, and accordingly, optical characteristics such as sensitivity of the pixels may change depending on the positions of the pixels. In addition, even if the CRA is the same, when an azimuthal angle of an incident light changes depending on the positions of the pixels, the optical characteristics of the pixels may change. As described above, there is a need to design unit lenses constituting a nano-optical lens array such that the optical characteristics of the pixels do not change according to changes in the CRA and the azimuthal angle.

Hereinafter, in order to reduce or avoid changes in the optical characteristics due to changes in the CRA and the azimuthal angle, an example embodiment is described in which three or more reference lenses are disposed at certain positions on an image sensor and designed to have different symmetrical structures, and unit lenses on an image sensor are designed to have continuously changing shapes (and/or continuously changing arrangements of the plurality of nanostructures) through interpolation based on shapes (and/or arrangements of the plurality of nanostructures) of the reference lenses.

FIG. 8 is a plan view illustrating a nano-optical lens array 250 of an image sensor according to an example embodiment.

Referring to FIG. 8, the nano-optical lens array 250 includes a plurality of reference lenses R1, R2, and R3 and a plurality of unit lenses N. The plurality of reference lenses R1, R2, and R3 may be respectively disposed at certain positions P1, P2, and P3 on the nano-optical lens array 250, and the plurality of unit lenses N may be positioned on all corresponding regions of the nano-optical lens array 250 except for the plurality of reference lenses R1, R2, and R3.

FIG. 8 shows coordinates in an x-y Cartesian coordinate system with the center of the nano-optical lens array 250 (or image sensor) as the origin, and the plurality of reference lenses R1, R2, and R3 and the plurality of unit lenses N arranged on the x-y Cartesian coordinates. Here, each of the plurality of reference lenses R1, R2, and R3 and the plurality of unit lenses N may have four meta-lenses, as described above with reference to FIG. 6.

The plurality of reference lenses R1, R2, and R3 may include the first reference lens R1, the second reference lens R2, and third reference lens R3. Here, the first reference lens R1, the second reference lens R2, and third reference lens R3 may be respectively disposed at a first position P1, a second position P2, and a third position P3 on the nano-optical lens array 250 (or image sensor). Also, as described below, the first reference lens R1, the second reference lens R2, and third reference lens R3 may be configured to have different symmetrical structures.

The first reference lens R1 may be disposed at the first position P1, which is the center of the nano-optical lens array 250. The second reference lens R2 may be disposed at the second position P2 in a first direction from the center of the nano-optical lens array 250. The third reference lens R3 may be disposed at the third position P3 in a second direction from the center of the nano-optical lens array 250. In the x-y coordinate system, the first reference lens R1 may be disposed at the origin, the second reference lens R2 may be disposed on a y=0 line and/or an x=0 line, and the third reference lens R3 may be disposed on an x=y line and/or an x=−y line. Hereinafter, the embodiment shown in FIG. 8 is described in detail.

The first reference lens R1 may be located at the center of the nano-optical lens array 250. In the x-y coordinate system, the first reference lens R1 may be located at the origin. The second reference lens R2 may be located in the first direction from the center of the nano-optical lens array 250. The first direction may be a major axis direction of the nano-optical lens array 250. In the x-y coordinate system, the second reference lens R2 may be located on the y=0 line (i.e., +x axis). In this case, the second reference lens R2 may be located at an outermost part of the nano-optical lens array 250 in the first direction.

The third reference lens R3 may be located in the second direction from the center of the nano-optical lens array 250. The second direction may be a direction forming an angle of +45° with the first direction with respect to the center of the nano-optical lens array 250. In the x-y coordinate system, the third reference lens R3 may be located on the x=y line of the first quadrant. In this case, the third reference lens R3 may be located at the outermost part of the nano-optical lens array 250 in the second direction.

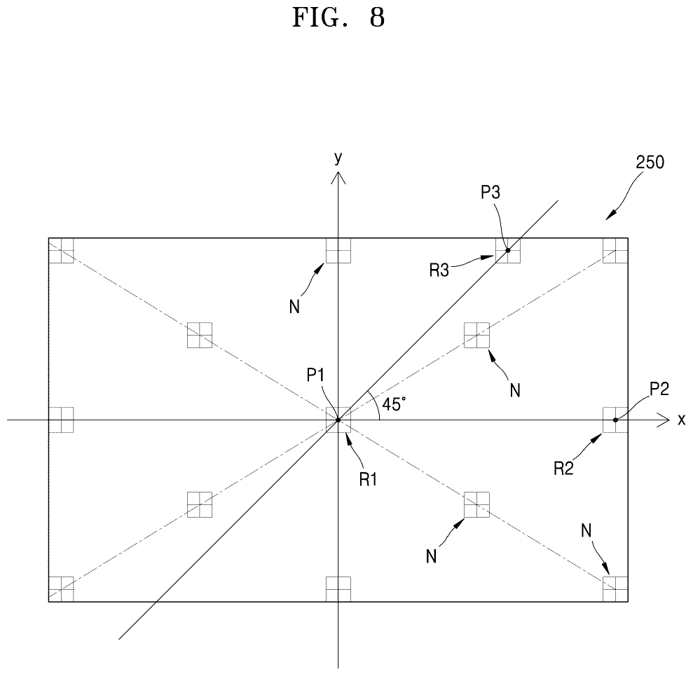

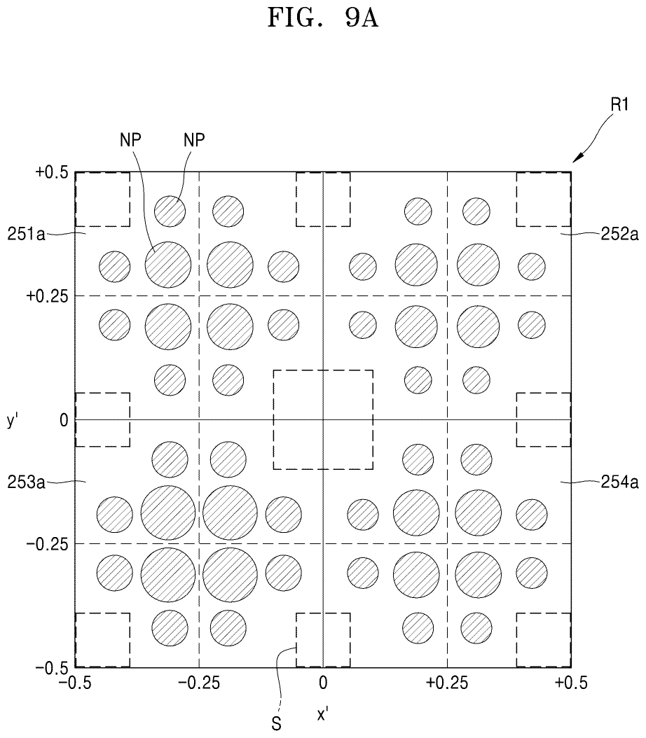

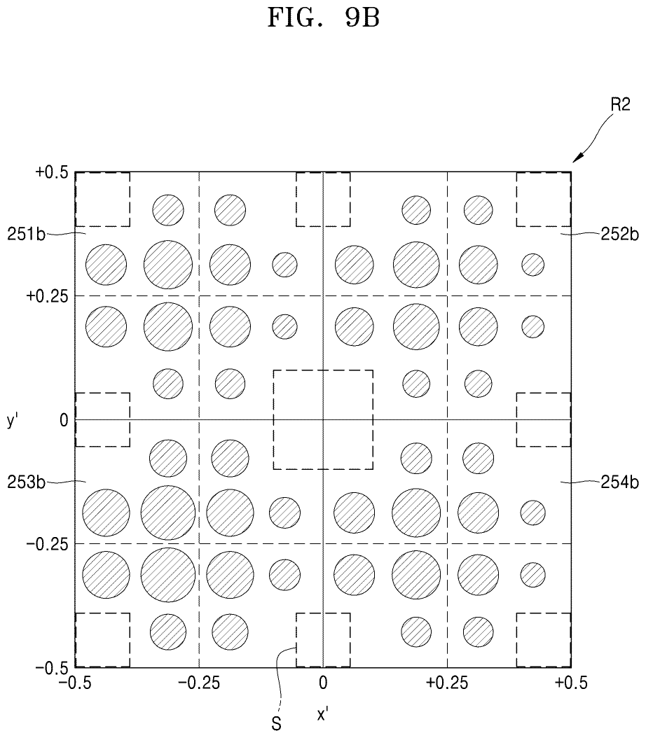

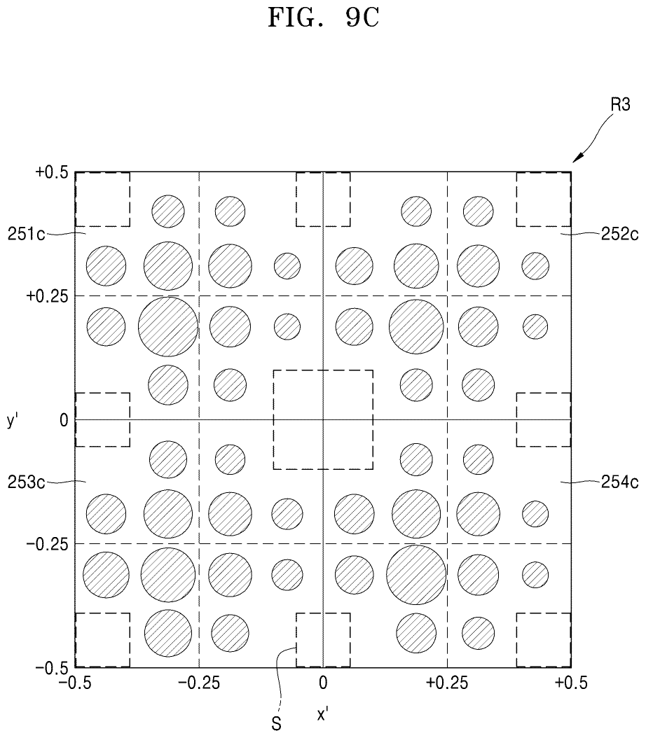

In an example embodiment, the first reference lens R1, the second reference lens R2, and the third reference lens R3 may be configured to have different symmetrical structures. FIGS. 9A to 9C show arrangements of the nanostructures NP respectively constituting the first reference lens R1, the second reference lens R2, and third reference lens R3 shown in FIG. 8. FIGS. 9A to 9C respectively show coordinates in an x′-y′ Cartesian coordinate system with a center of each of the first reference lens R1, the second reference lens R2, and third reference lens R3 as the origin, in which a size of each of the first reference lens R1, the second reference lens R2, and third reference lens R3 is normalized to 1×1.

FIG. 9A shows the arrangement of the nanostructures NP of the first reference lens R1 shown in FIG. 8.

Referring to FIG. 9A, the first reference lens R1 may include four meta-lenses, that is, a first meta-lens 251a, a second meta-lens 252a, a third meta-lens 253a, and a fourth meta-lens 254a. Here, each of the first meta-lens 251a, the second meta-lens 252a, the third meta-lens 253a, and the fourth meta-lens 254a has a structure in which the plurality of nanostructures NPs having a certain size(s) are arranged in a certain shape and/or certain arrangement pattern. For example, the first meta-lens 251a may correspond to a green pixel, the second meta-lens 252a may correspond to a blue pixel, the third meta-lens 253a may correspond to a red pixel, and the fourth meta-lens 254a may correspond to a green pixel.

As described above, the first reference lens R1 may be disposed at the center of the nano-optical lens array 250 (or image sensor). The first reference lens R1 may be disposed such that the nanostructures NP have a mirror symmetrical structure with respect to x′=y′, x′=+0.25, x′=−0.25, y′=+0.25, and y′=−0.25 lines in the x′-y′ coordinate system shown in FIG. 9A.

FIG. 9B shows the arrangement of nanostructures NP of the second reference lens R2 shown in FIG. 8.

Referring to FIG. 9B, the second reference lens R2 may include four meta-lenses, that is, four meta-lenses, that is, a first meta-lens 251b, a second meta-lens 252b, a third meta-lens 253b, and a fourth meta-lens 254b. Here, each of the first meta-lens 251b, the second meta-lens 252b, the third meta-lens 253b, and the fourth meta-lens 254b has a structure in which the plurality of nanostructures NPs having a certain size(s) are arranged in a certain shape and/or certain arrangement pattern.

The second reference lens R2 may be disposed in a first direction (e.g., the x-axis in the x-y coordinate system of FIG. 8) from the center of the nano-optical lens array 250 (or image sensor). The second reference lens R2 may be disposed such that the nanostructures NP have a mirror symmetrical structure with respect to y′=+0.25 and y′=−0.25 lines in the x′-y′ coordinate system shown in FIG. 9B. Although not shown in the drawing, the second reference lens R2 may be disposed on the y-axis in the x-y coordinate system of FIG. 8. In this case, the nanostructures NP may be disposed to have a mirror symmetrical structure with respect to x′=+0.25 and x′=−0.25 lines in the x′-y′ coordinate system shown in FIG. 9B.

FIG. 9C shows the arrangement of the nanostructures NP of the third reference lens R3 shown in FIG. 8.

Referring to FIG. 9C, the third reference lens R3 may include four meta-lenses, that is, a first meta-lens 251c, a second meta-lens 252c, a third meta-lens 253c, and a fourth meta-lens 254c. Here, each of the first meta-lens 251c, the second meta-lens 252c, the third meta-lens 253c, and the fourth meta-lens 254c has a structure in which the plurality of nanostructures NPs having a certain size(s) are arranged in a certain shape and/or certain arrangement pattern.

The third reference lens R3 may be disposed from the center of the nano-optical lens array 250 (or image sensor), in a second direction forming an angle of 45° with the first direction (e.g., x=y line of a first quadrant in the x-y coordinate system of FIG. 8). The third reference lens R3 may be disposed such that the nanostructures NP have a mirror symmetrical structure with respect to x′=y′ line in the x′-y′ coordinate system shown in FIG. 9C.

As described above, the first reference lens R1, the second reference lens R2, and third reference lens R3 may be disposed at certain positions of the nano-optical lens array 250 (or image sensor) and may be designed such that the nanostructures NP included in the first reference lens R1, the second reference lens R2, and the third reference lens R3 have different symmetrical structures as shown in FIGS. 9A to 9C.

The first reference lens R1, the second reference lens R2, and third reference lens R3 are designed with different symmetry conditions, and thus, interpolation of continuous and smooth microlens design without singularities is possible on the unit lenses N provided in the entire region of the nano-optical lens array 250 (or image sensor). Design interpolation on the unit lenses N may be flexibly performed depending on how parameters of the first reference lens R1, the second reference lens R2, and third reference lens R3 are defined.

Hereinafter, an interpolation method of designing the unit lenses N disposed in the entire region of the nano-optical lens array 250 (or image sensor) is described. However, the interpolation method described below is only an example.

Each of the first reference lens R1, the second reference lens R2, and third reference lens R3 described above may actually include hundreds of nanoposts. Here, when a radius of a jth nanopost in an ith reference lens is denoted by rᵢⱼ, a radius of a jth nanopost in a unit lens N at which a CRA is θ and an azimuthal angle Phi is φ may be interpolated using Equation (1) below such that radii of the nanoposts constituting the unit lenses N in the entire region of the image sensor may continuously change according to a position of the unit lenses N (or nanopost). This is merely an example and any other parameters such as a height or an arrangement interval of a nanopost may be continuously changed according to the positions thereof on the image sensor.

$${r}_{j} ( {θ}^{′} , {φ}^{′} ) = \sqrt{( 1 - {φ}^{′} ) ( ( 1 - {θ}^{′} ) {r}_{1 j}^{2} + {θ}^{′} {r}_{3 j}^{2} ) + {φ}^{′} ( ( 1 - {θ}^{′} ) {r}_{1 j}^{2} + {θ}^{′} {r}_{2 j}^{2} )} \\ Here , {θ}^{′} = θ / {CRA}_{max} , {φ}^{′} = φ / 45 deg \qquad [ Equation 1 ]$$

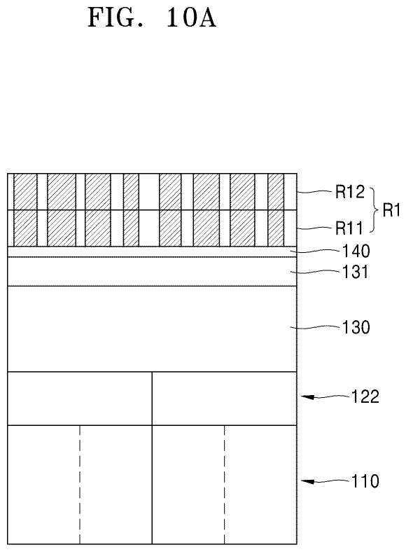

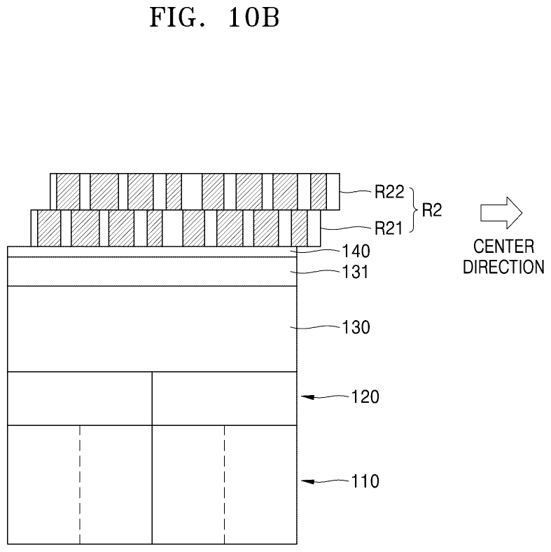

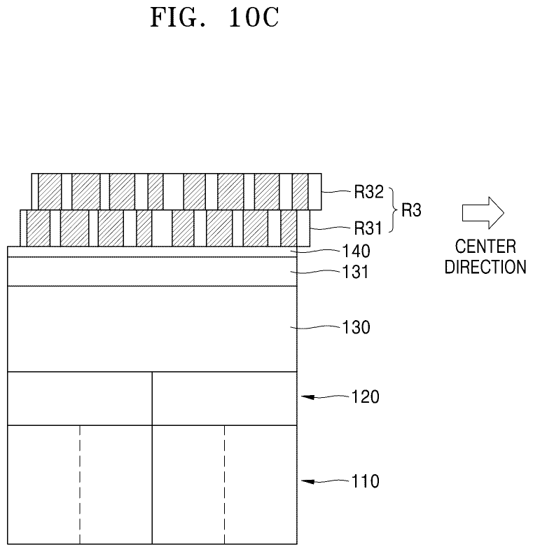

When the CRA of an incident light incident on the unit lens N is greater than 0 degree, the center of the unit lens N and its lower elements (or elements that are disposed on or below the unit lens N) may have an alignment error. The unit lens N may be disposed to have an alignment error with its lower elements according to a CRA of an incident light incident thereon. FIGS. 10A to 10C are cross-sectional views of an image sensor to which the first reference lens R1, the second reference lens R2, and third reference lens R3 are respectively applied. FIGS. 10A to 10C show that each of the first reference lens R1, the second reference lens R2, and third reference lens R3 includes two layers including nanostructures.

FIG. 10A is a cross-sectional view of the image sensor to which the first reference lens R1 shown in FIG. 9A is applied. Referring to FIG. 10A, the first reference lens R1 is located at the center of the nano-optical lens array 250 (or image sensor), and thus, the CRA of an incident light incident on the first reference lens R1 may be 0 degree. In this case, as shown in FIG. 10A, a first layer R11 and a second layer R12 constituting the first reference lens R1 may be aligned with their lower elements.

FIG. 10B is a cross-sectional view of the image sensor to which the second reference lens R2 shown in FIG. 9B is applied. Referring to FIG. 10B, the second reference lens R2 is located at the outermost part of the nano-optical lens array 250 (or image sensor) in a major axis direction, and thus, the CRA of an incident light incident on the second reference lens R2 may be relatively large. In this case, as shown in FIG. 10B, a first layer R121 and a second layer R22 constituting the second reference lens R2 may be shifted toward the center of the image sensor with a certain alignment error with respect to their lower elements.

FIG. 10C is a cross-sectional view of the image sensor to which the third reference lens R3 shown in FIG. 9C is applied. Referring to FIG. 10C, the third reference lens R3 may have a CRA of an incident light relatively less than that of the second reference lens R2. In this case, as shown in FIG. 10C, compared to the second reference lens R2, a first layer R31 and a second layer R32 of the third reference lens R3 have a relatively small alignment error with their lower elements and may be shifted toward the center of the image sensor.

As described above, an alignment error of the unit lenses N disposed in the entire region of the nano-optical lens array 250 (or image sensor) may also be continuously interpolated using the alignment error of the first reference lens R1, the second reference lens R2, and third reference lens R3.

According to an example embodiment, the first reference lens R1, the second reference lens R2, and third reference lens R3 may be disposed at different positions of the nano-optical lens array 250 (or image sensor) and may be designed to have different symmetrical structures, and the unit lenses N provided in the entire region of the nano-optical lens array 250 (or image sensor) may be designed to have continuously changing shapes (and/or continuously changing arrangement of the plurality of nanostructures NP) according to a position of the unit lens N through interpolation based on shapes (and/or arrangement of the plurality of nanostructures NP) of the first reference lens R1, the second reference lens R2, and third reference lens R3. Thus, changes in optical characteristics due to changes in the CRA and the azimuthal angle may be reduced.

In the above, the case where the third reference lens R3 is disposed on the x=y line of the first quadrant in the x-y coordinate system shown in FIG. 8 has been described as an example. However, the third reference lens R3 is not limited thereto and may also be disposed on the x=y line of a third quadrant in the x-y coordinate system shown in FIG. 8. In addition, the third reference lens R3 may be disposed in a second direction forming an angle of 135° with the x-axis direction shown in FIG. 8 with respect to the center of the nano-optical lens array 250 (or image sensor). In this case, the third reference lens R3 may be disposed on the x=−y line of a second quadrant or on the x=−y line of a fourth quadrant in the x-y coordinate system shown in FIG. 8.

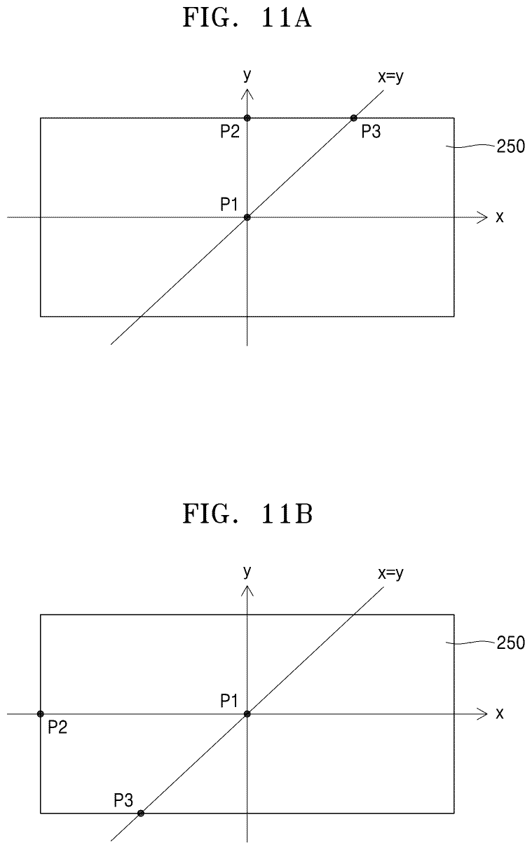

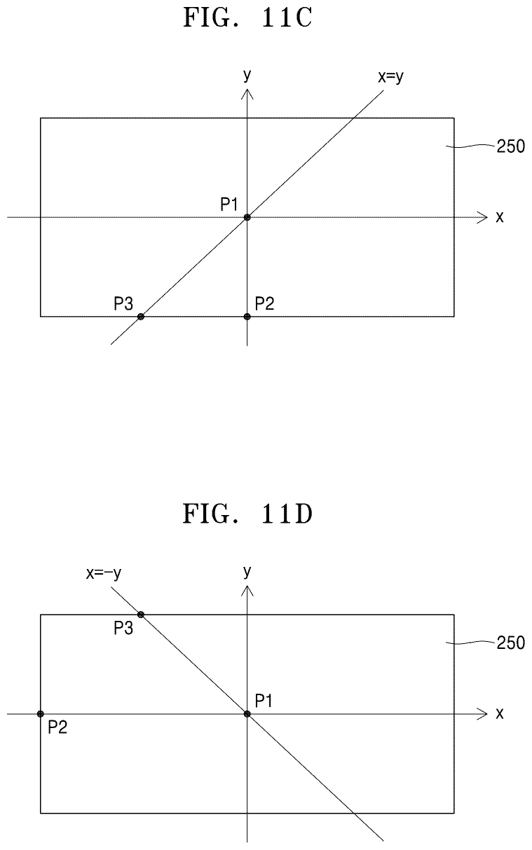

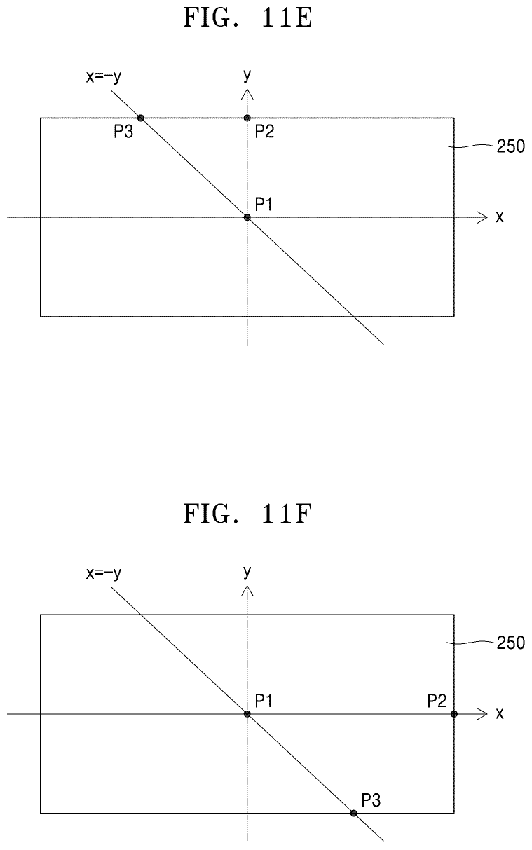

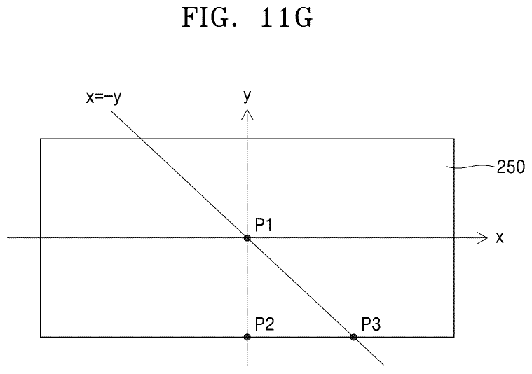

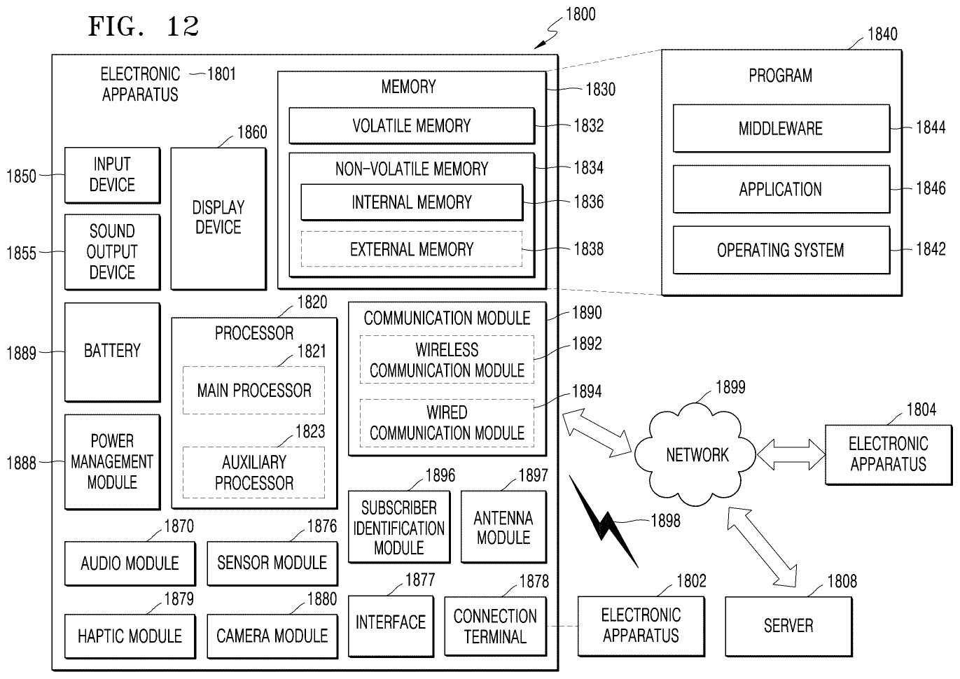

FIGS. 11A to 11G illustrate the first position P1, the second position P2, and the third position P3 where the first reference lens R1, the second reference lens R2, and third reference lens R3 may be disposed in the nano-optical lens array 250 (or image sensor) according to example embodiments. Hereinafter, it is assumed that each of the first reference lens R1, the second reference lens R2, and third reference lens R3 is disposed in the x′-y′ Cartesian coordinates with the center of the first reference lens R1, the second reference lens R2, or the third reference lens R3 as the origin as described above, and the size of each of the first reference lens R1, the second reference lens R2, and third reference lens R3 is normalized to 1.

Referring to FIG. 11A, the first reference lens R1, the second reference lens R2, and third reference lens R3 may be respectively disposed at the first position P1, which is the origin in the x-y coordinate system, the second position P2 on the +y axis (x=0 line), and the third position P3 on the x=y line of a first quadrant. Here, the second position P2 and the third position P3 may be at the outermost part of the nano-optical lens array 250 (or image sensor), and the same applies in the below descriptions. In the x′-y′ coordinate system, the first reference lens R1 may be disposed such that the nanostructures have a mirror symmetrical structure with respect to x′=y′, x′=+0.25, x′=−0.25, y′=+0.25, and y′=−0.25 lines, and the same applies in the below descriptions. In the x′-y′ coordinate system, the second reference lens R2 may be disposed such that the nanostructures have a mirror symmetrical structure with respect to x′=+0.25 and x′=−0.25 lines, and the third reference lens R3 may be disposed such that the nanostructures have a mirror symmetrical structure with respect to x′=y′ line.

Referring to FIG. 11B, the first reference lens R1, the second reference lens R2, and third reference lens R3 may be respectively disposed at the first position P1, which is the origin in the x-y coordinate system, the second position P2 on the −x axis (y=0 line), and the third position P3 on the x=y line of a third quadrant. In the x′-y′ coordinate system, the second reference lens R2 may be disposed such that the nanostructures have a mirror symmetrical structure with respect to y′=+0.25 and y′=−0.25 lines, and the third reference lens R3 may be disposed such that the nanostructures have a mirror symmetrical structure with respect to x′=y′ line.

Referring to FIG. 11C, the first reference lens R1, the second reference lens R2, and third reference lens R3 may be respectively disposed at the first position P1, which is the origin in the x-y coordinate system, the second position P2 on the −y axis (x=0 line), and the third position P3 on the x=y line of the third quadrant. In the x′-y′ coordinate system, the second reference lens R2 may be disposed such that the nanostructures have a mirror symmetrical structure with respect to x′=+0.25 and x′=−0.25 lines, and the third reference lens R3 may be disposed such that the nanostructures have a mirror symmetrical structure with respect to the x′=y′ line.

Referring to FIG. 11D, the first reference lens R1, the second reference lens R2, and third reference lens R3 may be respectively disposed at the first position P1, which is the origin in the x-y coordinate system, the second position P2 on the −x axis (y=0 line), and the third position P3 on the x=−y line of a second quadrant. In the x′-y′ coordinate system, the second reference lens R2 may be disposed such that the nanostructures have a mirror symmetrical structure with respect to y′=+0.25 and y′=−0.25 lines, and the third reference lens R3 may be disposed such that the nanostructures have a mirror symmetrical structure with respect to the x′=−y′ line.

Referring to FIG. 11E, the first reference lens R1, the second reference lens R2, and third reference lens R3 may be respectively disposed at the first position P1, which is the origin in the x-y coordinate system, the second position P2 on the +y axis (x=0 line), and the third position P3 on the x=−y line of the second quadrant. In the x′-y′ coordinate system, the second reference lens R2 may be disposed such that the nanostructures have a mirror symmetrical structure with respect to x′=+0.25 and x′=−0.25 lines, and the third reference lens R3 may be disposed such that the nanostructures have a mirror symmetrical structure with respect to the x′=−y′ line. Referring to FIG. 11F, the first reference lens R1, the second reference lens R2, and third reference lens R3 may be respectively disposed at the first position P1, which is the origin in the x-y coordinate system, the second position P2 on the +x axis (y=0 line), and the third position P3 on the x=−y line of a fourth quadrant. In the x′-y′ coordinate system, the second reference lens R2 may be disposed such that the nanostructures have a mirror symmetrical structure with respect to the γ′=+0.25 and y′=−0.25 lines, and the third reference lens R3 may be disposed such that the nanostructures have a mirror symmetrical structure with respect to the x′=−y′ line.

Referring to FIG. 11G, the first reference lens R1, the second reference lens R2, and third reference lens R3 may be respectively disposed at the first position P1, which is the origin in the x-y coordinate system, the second position P2 on the −y axis (x=0 line), and the third position P3 on the x=−y line of the fourth quadrant. In the x′-y′ coordinate system, the second reference lens R2 may be disposed such that the nanostructures have a mirror symmetrical structure with respect to the x′=+0.25 and x′=−0.25 lines, and the third reference lens R3 may be disposed such that the nanostructures have a mirror symmetrical structure with respect to the x′=−y′ line.

The image sensor 1000 described above may be employed in various high-performance optical devices and/or high-performance electronic apparatuses. The electronic apparatuses may include, for example, various portable devices such as smartphones, personal digital assistants (PDAs), laptops, PCs, etc., home appliances, security cameras, medical cameras, automobiles, Internet of Things (IoT) devices, other mobile or non-mobile computing devices, but are not limited thereto.

In addition to the image sensor 1000, an electronic apparatus may further include at least one processor that controls the image sensor 1000, for example, an application processor (AP), and may run an operating system or application program through the processor to control multiple hardware or software components and perform various data processing and calculations. The processor may further include a graphics processing unit (GPU) and/or an image signal processor. When the processor includes an image signal processor, an image (or video) acquired by the image sensor 1000 may be stored and/or output by using the processor.

FIG. 12 is a block diagram illustrating an example of an electronic apparatus 1801 including the image sensor 1000 according to some example embodiments.

Referring to FIG. 12, in a network environment 1800, the electronic apparatus 1801 may communicate with another electronic apparatus 1802 over a first network 1898 (e.g., short-range wireless communication network, etc.), or may communicate with another electronic apparatus 1804 and/or a server 1808 over a second network 1899 (e.g., long-range wireless communication network, etc.) The electronic apparatus 1801 may communicate with the electronic apparatus 1804 through the server 1808. The electronic apparatus 1801 may include a processor 1820, a memory 1830, an input device 1850, a sound output device 1855, a display device 1860, an audio module 1870, a sensor module 1876, an interface 1877, a haptic module 1879, a camera module 1880, a power management module 1888, a battery 1889, a communication module 1890, a subscriber identification module 1896, and/or an antenna module 1897. In the electronic apparatus 1801, some (e.g., display device 1860, etc.) of components may be omitted or another component may be added. Some of the components may be configured as one integrated circuit. For example, the sensor module 1876 (e.g., a fingerprint sensor, an iris sensor, an illuminance sensor, etc.) may be embedded and implemented in the display device 1860 (e.g., display, etc.)

The processor 1820 may control one or more components (e.g., hardware and software components, etc.) of the electronic apparatus 1801 connected to the processor 1820 by executing software (e.g., a program 1840, etc.), and may perform various data processes or operations. As a part of the data processes or operations, the processor 1820 may load a command and/or data received from another component (e.g., the sensor module 1876, the communication module 1890, etc.) to a volatile memory 1832, may process the command and/or data stored in the volatile memory 1832, and may store result data in a non-volatile memory 1834. The processor 1820 may include a main processor 1821 (e.g., central processing unit, AP, etc.) and an auxiliary processor 1823 (e.g., graphics processing unit, image signal processor, sensor hub processor, communication processor, etc.) that may be operated independently from or along with the main processor 1821. The auxiliary processor 1823 may use less power than that of the main processor 1821 and may perform specific functions.

The auxiliary processor 1823, on behalf of the main processor 1821 while the main processor 1821 is in an inactive state (e.g., sleep state) or along with the main processor 1821 while the main processor 1821 is in an active state (e.g., application executed state), may control functions and/or states related to some (e.g., the display device 1860, the sensor module 1876, the communication module 1890, etc.) of the components of the electronic apparatus 1801. The auxiliary processor 1823 (e.g., image signal processor, communication processor, etc.) may be implemented as a part of another component (e.g., the camera module 1880, the communication module 1890, etc.) that is functionally related thereto.

The memory 1830 may store a variety of data required by the components (e.g., the processor 1820, the sensor module 1876, etc.) of the electronic apparatus 1801. The data may include, for example, input data and/or output data about software (e.g., the program 1840, etc.) and commands related thereto. The memory 1830 may include the volatile memory 1832 and/or the non-volatile memory 1834.

The program 1840 may be stored as software in the memory 1830 and may include an operating system 1842, middleware 1844, and/or an application 1846.

The input device 1850 may receive commands and/or data to be used in the components (e.g., the processor 1820, etc.) of the electronic apparatus 1801, from outside (e.g., a user, etc.) of the electronic apparatus 1801. The input device 1850 may include a microphone, a mouse, a keyboard, and/or a digital pen (e.g., stylus pen).

The sound output device 1855 may output a sound signal to the outside of the electronic apparatus 1801. The sound output device 1855 may include a speaker and/or a receiver. The speaker may be used for a general purpose such as multimedia reproduction or record play, and the receiver may be used to receive a call. The receiver may be coupled as a part of the speaker or may be implemented as an independent device.

The display device 1860 may provide visual information to the outside of the electronic apparatus 1801. The display device 1860 may include a display, a hologram device, or a projector, and a control circuit for controlling the corresponding device. The display device 1860 may include touch circuitry set to sense a touch, and/or a sensor circuit (e.g., pressure sensor, etc.) that is set to measure the strength of a force generated by the touch.

The audio module 1870 may convert sound into an electrical signal or vice versa. The audio module 1870 may acquire sound through the input device 1850, or may output sound through the sound output device 1855 and/or a speaker and/or headphones of another electronic apparatus (e.g., the electronic apparatus 1802, etc.) connected directly or wirelessly to the electronic apparatus 1801.

The sensor module 1876 may sense an operating state (e.g., power, temperature, etc.) of the electronic apparatus 1801, or an outer environmental state (e.g., user state, etc.), and may generate an electrical signal and/or data value corresponding to the sensed state. The sensor module 1876 may include a gesture sensor, a gyro-sensor, a pressure sensor, a magnetic sensor, an acceleration sensor, a grip sensor, a proximity sensor, a color sensor, an infrared (IR) ray sensor, a vivo sensor, a temperature sensor, a humidity sensor, and/or an illuminance sensor.

The interface 1877 may support one or more designated protocols that may be used in order for the electronic apparatus 1801 to be directly or wirelessly connected to another electronic apparatus (e.g., electronic apparatus 1802, etc.) The interface 1877 may include a high-definition multimedia interface (HDMI), a universal serial bus (USB) interface, an SD card interface, and/or an audio interface.

The connection terminal 1878 may include a connector by which the electronic apparatus 1801 may be physically connected to another electronic apparatus (e.g., electronic apparatus 1802, etc.) The connection terminal 1878 may include an HDMI connector, a USB connector, an SD card connector, and/or an audio connector (e.g., headphone connector, etc.)

The haptic module 1879 may convert the electrical signal into a mechanical stimulation (e.g., vibration, motion, etc.) or an electric stimulation that the user may sense through a tactile or motion sensation. The haptic module 1879 may include a motor, a piezoelectric device, and/or an electric stimulus device.

The camera module 1880 may capture a still image and a video. The camera module 1880 may include a lens assembly including one or more lenses, the image sensor 1000 of FIG. 1, image signal processors, and/or flashes. The lens assembly included in the camera module 1880 may collect light emitted from an object that is an object to be captured.

The power management module 1888 may manage the power supplied to the electronic apparatus 1801. The power management module 1888 may be implemented as a part of a power management integrated circuit (PMIC).

The battery 1889 may supply electric power to the components of the electronic apparatus 1801. The battery 1889 may include a primary battery that is not rechargeable, a secondary battery that is rechargeable, and/or a fuel cell.

The communication module 1890 may support the establishment of a direct (e.g., wired) communication channel and/or a wireless communication channel between the electronic apparatus 1801 and another electronic apparatus (e.g., electronic apparatus 1802, electronic apparatus 1804, server 1808, etc.), and execution of communication through the established communication channel. The communication module 1890 may be operated independently from the processor 1820 (e.g., AP, etc.), and may include one or more communication processors that support the direct communication and/or the wireless communication. The communication module 1890 may include a wireless communication module 1892 (e.g., cellular communication module, a short-range wireless communication module, a global navigation satellite system (GNSS) communication module) and/or a wired communication module 1894 (e.g., local area network (LAN) communication module, a power line communication module, etc.) From among the communication modules, a corresponding communication module may communicate with another electronic apparatus over a first network 1809 (e.g., short-range communication network such as Bluetooth, WiFi direct, or infrared data association (IrDA)) or a second network 1899 (e.g., long-range communication network such as a cellular network, Internet, or computer network (e.g., LAN, WAN, etc.)). Such above various kinds of communication modules may be integrated as one component (e.g., single chip, etc.) or may be implemented as a plurality of components (e.g., a plurality of chips) separately from one another. The wireless communication module 1892 may identify and authenticate the electronic apparatus 1801 in a communication network such as the first network 1898 and/or the second network 1899 by using subscriber information (e.g., international mobile subscriber identifier (IMSI), etc.) stored in the subscriber identification module 1896.

The antenna module 1897 may transmit or receive the signal and/or power to/from outside (e.g., another electronic apparatus, etc.) An antenna may include a radiator formed as a conductive pattern formed on a substrate (e.g., PCB, etc.) The antenna module 1897 may include one or more antennas. When the antenna module 1897 includes a plurality of antennas, from among the plurality of antennas, an antenna that is suitable for the communication type used in the communication network such as the first network 1898 and/or the second network 1899 may be selected by the communication module 1890. The signal and/or the power may be transmitted between the communication module 1890 and another electronic apparatus through the selected antenna. Another component (e.g., RFIC, etc.) other than the antenna may be included as a part of the antenna module 1897.

Some of the components may be connected to one another by using the communication method among the peripheral devices (e.g., bus, general purpose input and output (GPIO), serial peripheral interface (SPI), mobile industry processor interface (MIPI), etc.) and may exchange signals (e.g., commands, data, etc.)

The command or data may be transmitted or received between the electronic apparatus 1801 and the external electronic apparatus 1804 through the server 1808 connected to the second network 1899. The other electronic apparatuses 1802 and 1804 may be the same kind as or different kinds from that of the electronic apparatus 1801. All or some of the operations executed by the electronic apparatus 1801 may be executed by one or more apparatuses among the other electronic apparatuses 1802, 1804, and 1808. For example, when the electronic apparatus 1801 has to perform a certain function or service, the electronic apparatus 1801 may request one or more other electronic apparatuses to perform some or entire function or service, instead of executing the function or service by itself. One or more electronic apparatuses receiving the request execute an additional function or service related to the request and may transfer a result of the execution to the electronic apparatus 1801. To this end, cloud computing, distributed computing, or client-server computing technique may be used.

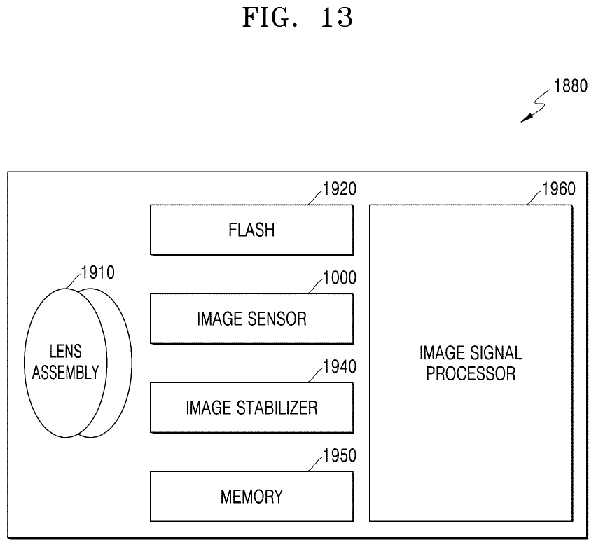

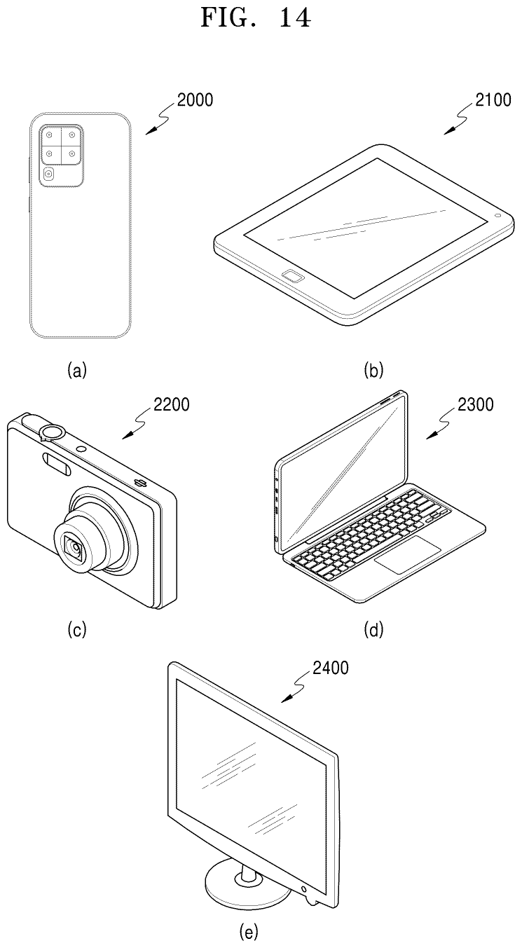

FIG. 13 is a block diagram schematically illustrating the camera module 1880 of FIG. 12.

Referring to FIG. 13, the camera module 1880 may include a lens assembly 1910, a flash 1920, the image sensor 1000 (see FIG. 1), an image stabilizer 1940, a memory 1950 (e.g., buffer memory, etc.), and/or an image signal processor 1960. The lens assembly 1910 may collect light emitted from an object that is to be captured. The camera module 1880 may include a plurality of lens assemblies 1910, and in this case, the camera module 1880 may include a dual camera module, a 360-degree camera, or a spherical camera. Some of the plurality of lens assemblies 1910 may have the same lens properties (e.g., viewing angle, focal distance, auto-focus, F number, optical zoom, etc.) or different lens properties. The lens assembly 1910 may include a wide-angle lens or a telephoto lens.

The flash 1920 may emit light that is used to strengthen the light emitted or reflected from the object. The flash 1920 may include one or more light-emitting diodes (e.g., red-green-blue (RGB) LED, white LED, infrared LED, ultraviolet LED, etc.), and/or a Xenon lamp. The image sensor 1000 may be the image sensor described above with reference to FIG. 1, and converts the light emitted or reflected from the object and transferred through the lens assembly 1910 into an electrical signal to obtain an image corresponding to the object. The image sensor 1000 may include one or a plurality of sensors selected from the image sensors having different properties, such as an RGB sensor, a black and white (BW) sensor, an IR sensor, or a UV sensor. Each of sensors included in the image sensor 1000 may be implemented as a CCD sensor and/or a CMOS sensor.

The image stabilizer 1940, in response to a motion of the camera module 1880 or the electronic apparatus 1901 including the camera module 1880, moves one or more lenses included in the lens assembly 1910 or the image sensor 1000 in a certain direction or controls the operating characteristics of the image sensor 1000 (e.g., adjusting of a read-out timing, etc.) in order to compensate for a negative influence of the motion. The image stabilizer 1940 may sense the movement of the camera module 1880 or the electronic apparatus 1801 by using a gyro sensor (not shown) or an acceleration sensor (not shown) arranged inside or outside the camera module 1880. The image stabilizer 1940 may be implemented as an optical type.

The memory 1950 may store some or entire data of the image obtained through the image sensor 1000 for next image processing operation. For example, when a plurality of images are obtained at a high speed, obtained original data (e.g., Bayer-patterned data, high resolution data, etc.) is stored in the memory 1950, and a low resolution image is only displayed. Then, original data of a selected image (e.g., user selection, etc.) may be transferred to the image signal processor 1960. The memory 1950 may be integrated with the memory 1830 of the electronic apparatus 1801, or may include an additional memory that operates independently.

The image signal processor 1960 may perform image processing operations on the image obtained through the image sensor 1000 or the image data stored in the memory 1950. The image processing operations may include depth map generation, three-dimensional modeling, panorama generation, extraction of features, an image combination, and/or an image compensation (e.g., noise reduction, resolution adjustment, brightness adjustment, blurring, sharpening, softening, etc.) The image signal processor 1960 may perform control operations (e.g., exposure time control, read-out timing control, etc.) on the components (e.g., image sensor 1000, etc.) included in the camera module 1880. The image processed by the image signal processor 1960 may be stored again in the memory 1950 for additional process, or may be provided to an external component of the camera module 1880 (e.g., the memory 1830, the display device 1860, the electronic apparatus 1802, the electronic apparatus 1804, the server 1808, etc.) The image signal processor 1960 may be integrated with the processor 1820, or may be configured as an additional processor that is independently operated from the processor 1820. When the image signal processor 1960 is configured as an additional processor separately from the processor 1820, the image processed by the image signal processor 1960 may undergo through an additional image processing operation by the processor 1820 and then may be displayed on the display device 1860.

The electronic apparatus 1801 may include a plurality of camera modules 1880 having different attributes or functions. In this case, one of the camera modules 1880 may be a wide angle camera, and another may be a telescopic camera. Similarly, one of the camera modules 1880 may be a front side camera, and another may be a read side camera.

The image sensor 1000 according to some embodiments may be applied to a mobile phone or smartphone 2000 illustrated in FIG. 14A, a tablet or smart tablet 2100 illustrated in FIG. 14B, a digital camera or camcorder 2200 illustrated in FIG. 14C, a notebook computer 2300 illustrated in FIG. 14D, a television or smart television 2400 illustrated in FIG. 14E, etc. For example, the smartphone 2000 or the smart tablet 2100 may include a plurality of high resolution cameras, each having a high resolution image sensor mounted thereon. Depth information of subjects in an image may be extracted by using high resolution cameras, out focusing of the image may be adjusted, or subjects in the image may be automatically identified.

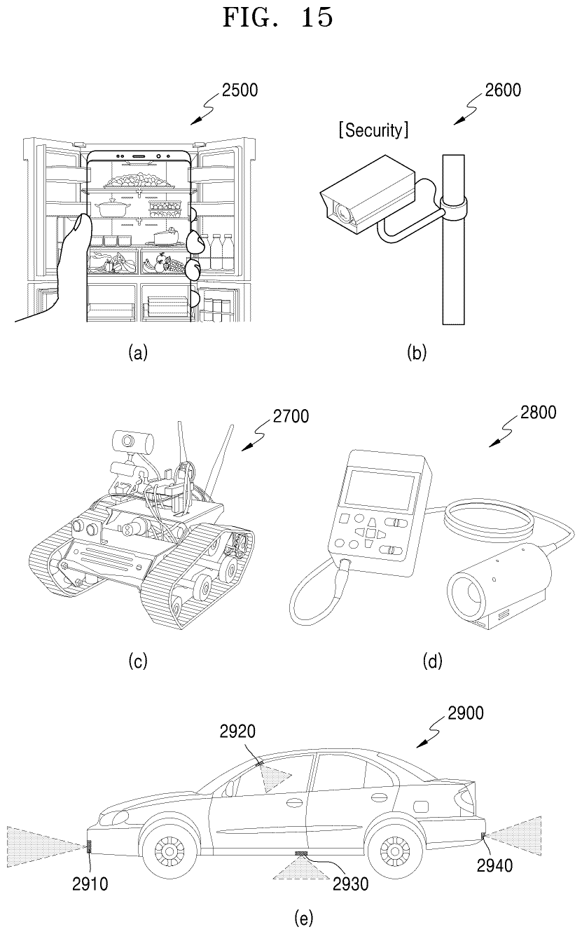

Furthermore, the image sensor 1000 may be applied to a smart refrigerator 2500 illustrated in FIG. 15A, a security camera 2600 illustrated in FIG. 15B, a robot 2700 illustrated in FIG. 15C, a medical camera 2800 illustrated in FIG. 15D, etc. For example, the smart refrigerator 2500 may automatically recognize food in a refrigerator, by using the image sensor 1000, and notify a user of the presence of a particular food, the type of food that is input or output, and the like, through a smartphone. The security camera 2600 may provide an ultrahigh resolution image and may recognize an object or a person in an image in a dark environment by using high sensitivity. The robot 2700 may be provided in a disaster or industrial site that is not directly accessible by people, and may provide a high-resolution image. The medical camera 2800 may provide a high-resolution image for diagnosis or surgery, and thus a field of vision may be dynamically adjusted.

Furthermore, the image sensor 1000 may be applied to a vehicle 2900 as illustrated in FIG. 15E. The vehicle 2900 may include a plurality of vehicle cameras 2910, 2920, 2930, and 2940 arranged at various positions. Each of the vehicle cameras 2910, 2920, 2930, and 2940 may include the image sensor 1000 according to an example embodiment. The vehicle 2900 may provide a driver with various pieces of information about the inside or periphery of the vehicle 2900, by using the vehicle cameras 2910, 2920, 2930, and 2940, thereby providing an object or a person in an image may be automatically recognized and information needed for autonomous driving.

According to an example embodiment described above, the three or more reference lenses R1, R2, and R3 are disposed at different positions on the nano-optical lens array (or image sensor), and are designed to have different symmetrical structures, and the unit lenses N provided in the entire region of the nano-optical lens array (or image sensor) are designed to have continuously changing shapes (and/or continuously changing arrangement patterns of the plurality of nanostructures NP) from the reference lenses R1, R2, and R3 through interpolation, and thus, changes in optical characteristics due to changes in the CRA and the azimuthal angle may be reduced.

It should be understood that example embodiments described herein should be considered in a descriptive sense only and not for purposes of limitation. Descriptions of features or aspects within each embodiment should typically be considered as available for other similar features or aspects in other embodiments. While one or more example embodiments have been described with reference to the figures, it will be understood by those of ordinary skill in the art that various changes in form and details may be made therein without departing from the spirit and scope as defined by the following claims and their equivalents.

What is claimed is:

1. An image sensor comprising:
a sensor substrate comprising a plurality of sensing elements;
a color filter layer disposed on the sensor substrate and comprising a plurality of color filters, each color filter of the plurality of color filters being configured to transmit a light of a specific wavelength band; and
a nano-optical lens array disposed on the color filter layer and comprising a plurality of nanostructures configured to condense an incident light toward the plurality of sensing elements,
wherein the nano-optical lens array comprises a plurality of reference lenses and a plurality of unit lenses,
wherein the plurality of reference lenses comprise:
a first reference lens disposed at a center of the image sensor;
a second reference lens disposed in a first direction from the center of the image sensor; and
a third reference lens disposed in a second direction from the center of the image sensor, the second direction forming an angle of 45° or 135° with the first direction, and
wherein nanostructures included in the first reference lens, the second reference lens, and the third reference lens have different symmetrical structures.

2. The image sensor of claim 1, wherein the second reference lens and the third reference lens are disposed on an outermost part of the image sensor.

3. The image sensor of claim 1, wherein, in an x-y Cartesian coordinate system with the center of the image sensor as an origin, the first reference lens is disposed at the origin,
wherein the second reference lens is disposed on a y=0 line and/or an x=0 line, and
wherein the third reference lens is disposed on an x=y line and/or an x=−y line.

4. The image sensor of claim 3, wherein, in an x′-y′ Cartesian coordinate system with a center of the first reference lens as an origin, a normalized size of the first reference lens is 1×1, and
wherein nanostructures included in the first reference lens are arranged to have a mirror symmetrical structure with respect to x′=y′, x′=+0.25, x′=−0.25, y′=+0.25, and y′=−0.25.

5. The image sensor of claim 3, wherein, in an x′-y′ Cartesian coordinate system with a center of the second reference lens as an origin, a normalized size of the second reference lens is 1×1, and
wherein nanostructures included in the second reference lens are arranged to have a mirror symmetrical structure with respect to y′=+0.25 and y′=−0.25.

6. The image sensor of claim 3, wherein, in an x′-y′ Cartesian coordinate system with a center of the third reference lens as an origin, a normalized size of the third reference lens is 1×1, and
wherein nanostructures included the third reference lens are arranged to have a mirror symmetrical structure with respect to x′=y′.

7. The image sensor of claim 1, wherein nanostructures included in each unit lens of the plurality of unit lenses are configured to have a continuously changing shape and/or arrangement according to positions of the nanostructures on the image sensor, through interpolation based on nanostructures included in each of the first reference lens, the second reference lens, and the third reference lens.

8. The image sensor of claim 7, wherein the positions of the nanostructures on the image sensor are determined through a chief ray angle (CRA) and an azimuthal angle of an incident light.

9. The image sensor of claim 1, wherein the nano-optical lens array has at least one layer, and the at least one layer includes two or more materials having different refractive indices.

10. The image sensor of claim 9, wherein the at least one layer is disposed to have an alignment error with the sensor substrate according to a CRA of an incident light.

11. The image sensor of claim 1, wherein a size of each of the plurality of nanostructures is smaller than a wavelength of a visible light.

12. The image sensor of claim 1, wherein each of the plurality of nanostructures includes at least one of c-Si, p-Si, a-Si, Group III-V compound semiconductor, SiC, TiO₂, SiN₃, ZnS, ZnSe, or Si₃N₄.

13. The image sensor of claim 1, further comprising an anti-reflection layer provided on the nano-optical lens array.

14. The image sensor of claim 1, further comprising a planarization layer disposed between the color filter layer and the nano-optical lens array.

15. The image sensor of claim 14, further comprising an encapsulation layer disposed between the planarization layer and the nano-optical lens array.

16. The image sensor of claim 15, further comprising an etch stop layer disposed between the encapsulation layer and the nano-optical lens array.

17. An electronic apparatus comprising:
a lens assembly configured to form an optical image of an object;
an image sensor configured to convert the optical image formed by the lens assembly into an electrical signal; and
at least one processor configured to process the electrical signal generated by the image sensor,
wherein the image sensor comprises:
a sensor substrate comprising a plurality of sensing elements;
a color filter layer disposed on the sensor substrate and comprising a plurality of color filters, each color filter of the plurality of color filters being configured to transmit a light of a specific wavelength band; and
a nano-optical lens array disposed on the color filter layer and comprising a plurality of nanostructures configured to condense an incident light toward the plurality of sensing elements,
wherein the nano-optical lens array comprises a plurality of reference lenses and a plurality of unit lenses,
wherein the plurality of reference lenses comprise:
a first reference lens disposed at a center of the image sensor;
a second reference lens disposed in a first direction from the center of the image sensor; and
a third reference lens disposed in a second direction from the center of the image sensor, the second direction forming an angle of 45° or 135° with the first direction, and
wherein nanostructures included in the first reference lens, the second reference lens, and the third reference lens have different symmetrical structures.

18. The electronic apparatus of claim 17, wherein the second reference lens and the third reference lens are disposed on an outermost part of the image sensor.

19. The electronic apparatus of claim 17, wherein, in an x-y Cartesian coordinate system with the center of the image sensor as an origin, the first reference lens is disposed at the origin,
